(19) United States
(12) Patent Application Publication
(10) Pub. No.: US 2003/0096511 A1
(43) Pub. Date: May 22, 2003

(54) Electrical pin contact

(76) Inventor: Tan Nguyen, Lancaster, PA (US)

Correspondence Address: Woodcock Washburn LLP, 46th Floor, One Liberty Place, Philadelphia, PA, 19103, US

(21) Appl. No.: 09/990,068

(22) Filed: Nov. 21, 2001

(51) Int. Cl. H05K 1/00

(52) U.S. Cl. 439/63

(57) ABSTRACT

The invention includes an electrical contact capable of mating with an electrical connector. The electrical contact has an intermediate contact having a flexible connection medium, and an outer contact surrounding the intermediate contact. The electrical contact also has a first insulator surrounding the intermediate contact and the flexible connection medium. The first insulator provides electrical isolation of the intermediate contact from the outer contact. The front insulator also has a front face that protects the flexible connection medium from being distorted by an electrical connector. The outer contact surrounds the first insulator, and a center contact is surrounded by the intermediate contact. The front face may have a flange that isolates a front portion of the flexible connection medium from the mating connector.

### FIELD OF THE INVENTION

The invention relates to the field of electrical connectors. More specifically, the invention relates to pin contacts having flexible connection members.

### BACKGROUND OF THE INVENTION

Many applications require multiple transmission paths between electrical components. For such applications, certain electrical cables have been developed to satisfy the multiple conducting paths. These electrical cables often also provide shielding to protect the multiple conducting paths from the undesired effect of electromagnetic interference. One type of cable that provides these multiple conducting paths is known in the industry as a “triaxial” cable. The triaxial cable typically has a center wire conductor surrounded by a first dielectric with braided shield layers. The first dielectric in turn is surrounded by a second dielectric with braided shield layers.

Although these cables serve a necessary purpose, in practice, their use has been limited by the industry's failure to develop inexpensive and suitable connecting devices to satisfy their particular applications. A triaxial pin contact is one such connecting device that is designed to be connected to a triaxial cable on one end (i.e., “cable interface”), and to a mating triaxial connector on the other end (i.e., “coupling interface”). The cable interface often provides any number of connections, such as either a solderable or crimpable connection to the triaxial cable. The coupling interface typically has either a male or female contact adapted to receive a corresponding female or male triaxial connector, respectively.

One problem typically is found in male triaxial pin contacts having a flexible intermediate contact interface. These male triaxial pin contacts are designed to receive female contacts of various shapes and sizes. However, certain female contacts as well as other objects may bend and distort the male contact's flexible intermediate contact interface beyond its intended boundaries. For example, a female connector or other object may tend to bend the flexible intermediate contact inward and toward another contact, called the center contact. As a result, the flexible intermediate contact undesirably touches the center contact, thus making the pin contact unusable. Although this problem has been described with reference to a male triaxial pin contact, the problem exists in any type of contact having a flexible contact interface.

Therefore, there is a need to provide a pin contact that protects the flexible contact medium from being bent and damaged.

### SUMMARY OF THE INVENTION

The invention includes an electrical contact capable of mating with an electrical connector. The electrical contact has an intermediate contact having a flexible connection medium, and an outer contact surrounding the intermediate contact. The electrical contact also has a first insulator surrounding the intermediate contact and the flexible connection medium. The first insulator provides electrical isolation of the intermediate contact from the outer contact. The front insulator also has a front face that protects the flexible connection medium from being distorted by an electrical connector. The outer contact surrounds the first insulator, and a center contact is surrounded by the intermediate contact. The front face may have a flange that isolates a front portion of the flexible connection medium from the mating connector. The front face also may have a ledge, such that a front portion of the flexible connection medium is located below the ledge. The front portion of the flexible connection medium may have a taper that guides the mating connector within the flexible connection medium.

The electrical contact also may have a second insulator located between the intermediate contact and the center contact. The second insulator may provide electrical isolation of the center contact from the intermediate contact. The electrical contact also may have a third insulator surrounding the center contact. The third insulator provides electrical isolation of the center contact. The center contact may be connected to a center pin that extends from a rear side of the outer contact such that the center contact is within a plane of the outer contact. The center pin may carry a data or ground signal. The intermediate contact may be connected to an intermediate pin that extends fiom a rear side of the outer contact such that the center contact is within a plane of the outer contact. The intermediate pin may carry a data or ground signal. The outer contact may be connected to an outer pin that extends from a rear side of the outer contact such that the center contact is within a plane of the outer contact. The outer pin may carry a data or ground signal.

### BRIEF DESCRIPTION OF THE DRAWINGS

Other uses and advantages of the invention will become apparent to those skilled in the art upon reference to the specification and the drawings, in which:

FIG. 1 is an exploded isometric view of a triaxial pin contact, according to the invention;

FIG. 2 provides a front view of an assembled triaxial pin contact, according to the invention;

FIG. 3 provides a rear view of the assembled triaxial pin contact, according to the invention and

FIG. 4 provides a front cut away view of the assembled triaxial pin contact, according to the invention.

### DETAILED DESCRIPTION OF THE INVENTION

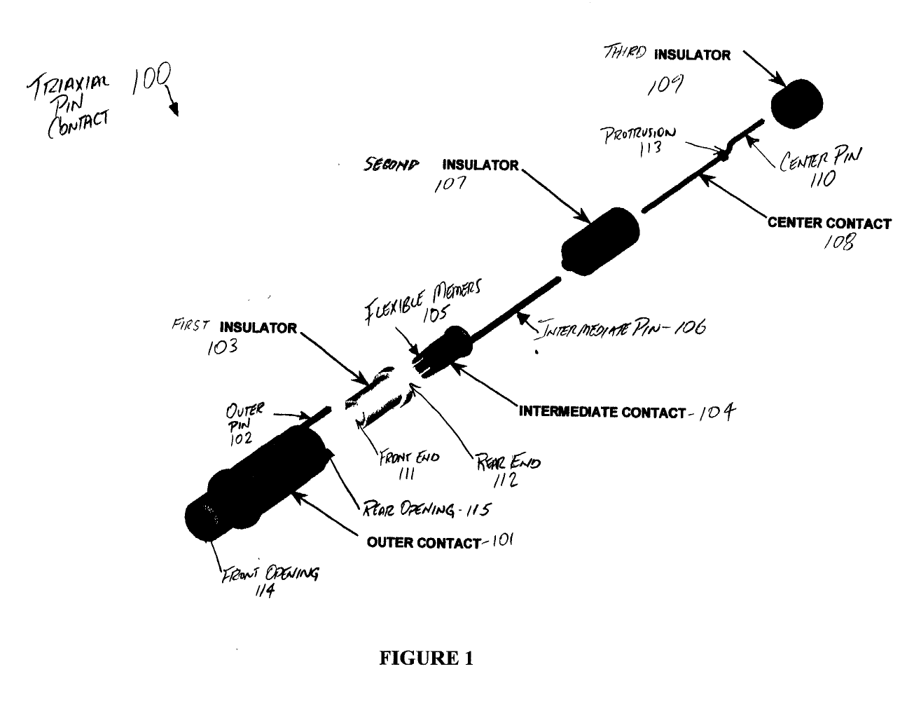

FIG. 1 is an exploded isometric view of one example embodiment of a triaxial pin contact 100. As shown in FIG. 1, triaxial pin contact 100 includes an outer contact 101. Outer contact 101 may be may be constructed of a brass alloy or other suitable material substance. Outer contact 101 has a front opening 114, a rear opening 115, and an outer pin 102 attached to its rear portion. As will be discussed further, outer pin 102 extends beyond rear opening 115 of outer contact 101 to facilitate the connection of outer contact 101 with a communication medium. Such communication medium may include a cable or substrate (e.g., printed circuit board). Outer pin 102 may carry a ground potential or signal between the communication medium and outer contact 101. Front opening 114 receives a corresponding mating connector.

A first insulator 103 fits within outer contact 101 and provides an insulative barrier between the signal or ground conducting outer contact 101 and an intermediate contact 104. First insulator may be constructed of a plastic or polymer compound, for example Victrex Peek™ polymer, manufactured by Victrex. Intermediate contact 104 may be constructed of a copper alloy or other suitable material substance. First insulator 103 and outer contact 101 may have an interference fit such that a front end 111 of first insulator 103 fits securely within front opening 114 of outer contact 101.

First insulator 103 also has a rear end 112 that receives an intermediate contact 104. Intermediate contact 104 has flexible members 105 that act as “fingers” in conducting a signal or ground to an intermediate pin 106, located on the rear portion of intermediate contact 104. Intermediate contact 104 and first insulator 103 may have an interference fit such that the front portion of intermediate contact 104 (i.e., flexible members 105) fits securely with front end 111 of first insulator 103. Moreover, front end 111 of first insulator 103 has a surface that protects flexible members 105 from being undesirably bent or distorted. Such damage typically is referred to in the industry as probe damage and/or over-sized pin damage, for example. For example, front end 111 of first insulator 103 may be have a taper or other surface that prevents a mating connector or other object from accessing the exterior side of flexible members 105, so as to undesirably bend flexible members 105.

A second insulator 107 has through holes to receive and electrically isolate intermediate pin 106 and intermediate contact 104 from a center contact 108. Center contact 108 may be constructed of a copper alloy or other suitable material substance. Second insulator 107 may be made from a plastic, rubber or other insulating material. Center contact 108 may be positioned to be located within the center, or nearly so, of both outer contact 101 and intermediate contact 104 by second insulator 107. Also, second insulator 107 may be in an interference fit with a protrusion 113 on center contact 108. The interference fit of second insulator 107 and protrusion 113 permits a front end of center contact 108 to be at or near front opening 114 of outer contact 101, such that center contact 108 may make electrical connection with a mating connector entering front opening 114 of outer contact 101.

Center contact 108 also has a center pin 110 on its rear portion. Center pin 110 permits a ground or signal to be carried from a mating connector that makes contact with the front end of center contact 108 to a communication medium (e.g., cable or substrate) connected to center pin 110. A third insulator 109 has through holes that permit the passage of center pin 110, intermediate pin 106, and outer pin 102. Second insulator 107 may be made from a plastic, rubber or other insulating material. Third insulator 109 fits within rear opening 115 of outer contact 101. Third insulator 109 may be made from a plastic, rubber or other insulating material.

Although triaxial pin contact 100 is shown in FIG. 1 as having a substantially circular shape, it should be appreciated that the components in triaxial contact 100 may have any shape suitable for a particular application. For example, in certain applications triaxial contact may have a tubular or square shape. Furthermore, it should be appreciated that the invention contemplates any type of pin contact, including those other than triaxial pin contacts, that require the protection of flexible members (like flexible members 105) from being distorted and bent. For example, the invention contemplates a contact, similar to the contact in FIG. 1 that does not have a center contact. In this case, insulator 103 protects flexible members 105 from becoming bent and unusable by either a mating connector or another foreign object.

Triaxial pin contact 100 may be used in any connector application. For example, triaxial pin contact may be constructed in accordance with MIL-C-39029/90A specification requirements.

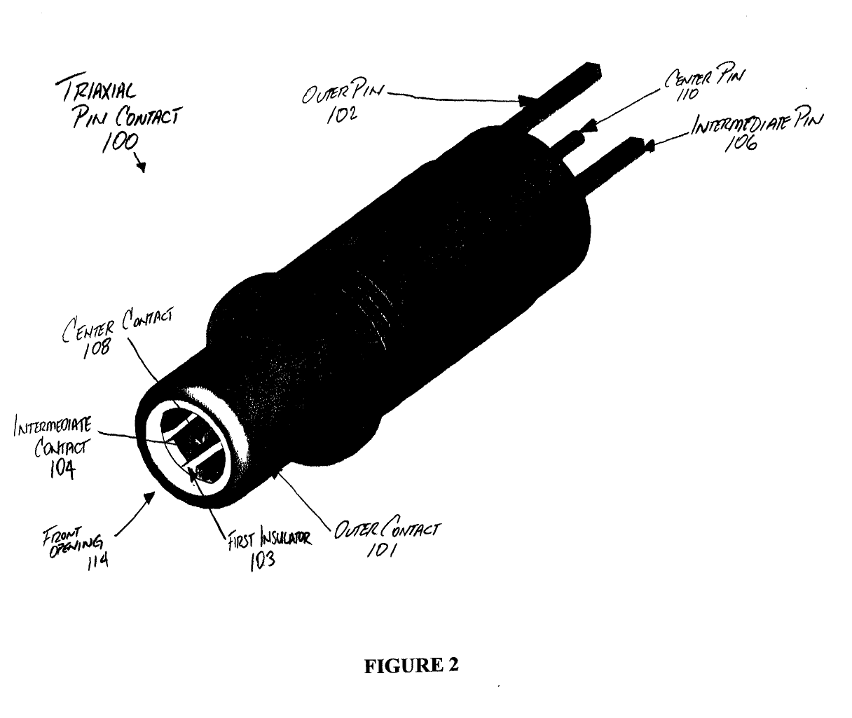

FIG. 2 provides a front view of an assembled triaxial pin contact 100. As shown in FIG. 2, triaxial pin contact 100 has front opening 114. Front opening 114 receives a mating connector. Front opening 114 provides a mating connector with access to outer contact 101, intermediate contact 104, and center contact 108. Front opening 114 also provides a corresponding mating connector with access to first insulator 103. More specifically, first insulator 103 protects flexible members 105 of intermediate contact 104 from undesirably being bent by the mating connector or any other object that may come into contact with triaxial pin contact 100. Such protection may be accomplished using a number of techniques and structures contemplated by the invention.

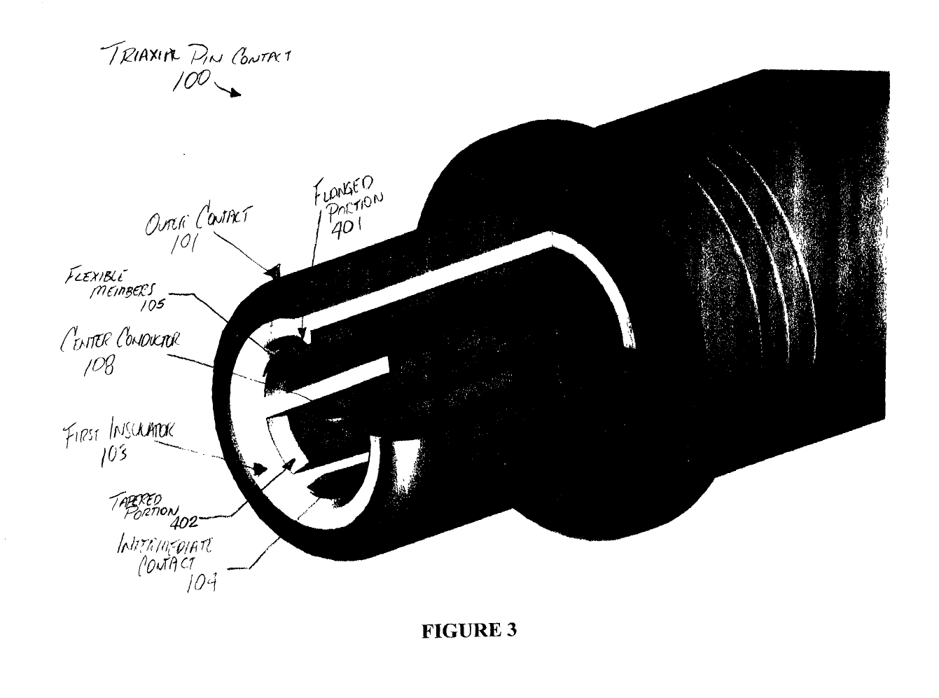

FIG. 3 provides a cut away view of the assembled triaxial pin contact 100, further detailing the protection of flexible members 105. As shown in FIG. 3, first insulator 103 has a flanged portion 301, under which the front end of flexible members 105 is seated. Flanged portion 301 provides a protective “ledge” or curved rim under which flexible members 105 are located. A mating connector designed to accept center conductor 108 and to make contact with flexible members 105 and intermediate contact 104 will ride along flanged portion 301. By directing the mating connector in such a way, the mating connector is ensured of properly making contact with the interior portion of intermediate contact 104, and not making an improper connection with the exterior portion of intermediate contact 104. Preventing contact with the exterior portion of intermediate contact 104 keeps the mating connector from undesirably bending flexible members 105 inward, and perhaps making an electrical connection between flexible members 105 and center conductor 108.

In addition to flanged portion 301, flexible members 105 may have a tapered portion 302. Tapered portion 302 further protects the exterior portion of flexible members 105 from being undesirably contacted by a mating connector. Tapered portion 302 permits flexible members 105 to act as a ramp-like guide in shepherding the mating connector within intermediate contact 104, thus making electrical connection with the interior of flexible members 105. Tapered portion 302 may be tapered in an outward direction toward an outer boundary of outer contact 101.

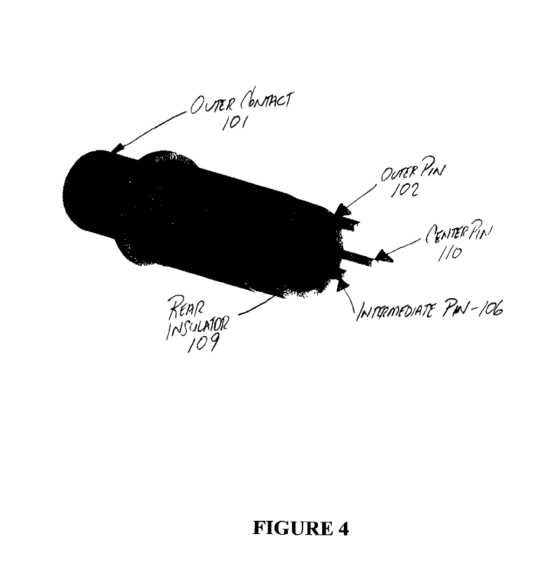

FIG. 4 provides a rear view of the assembled triaxial pin contact 100, further detailing one example of the layout of outer pin 102, center pin 110, and intermediate pin 106. As shown in FIG. 4, intermediate pin 106 and center pin 110 are located within the circumferential area of triaxial pin contact 100. In one embodiment, for example, center pin 110 may be located at the center of the rear portion of triaxial pin contact 100. Outer pin 102 is attached to outer contact 101 and thus may be located on the outside rear insulator 109. Alternatively, outer pin 102 may be located on the interior portion of the shell of outer contact 101, and thus pass through rear insulator 109.

The length and shape of outer pin 102, center pin 110, and intermediate pin 106 may vary depending upon the particular application. For example, outer pin 102, center pin 110, and intermediate pin 106 may be substantially circular or substantially square. In addition, the diameter (i.e., if circular) or surface contact area (i.e., if square) may be of any size depending upon the desired application. Furthermore, as discussed, each of outer pin 102, center pin 110, and intermediate pin 106 may carry a data signal and/or ground signal from the connecting medium to a mating connector inserted into front opening 114 of triaxial pin contact 100.

The invention is directed to an electrical connection device. It is noted that the foregoing examples have been provided merely for the purpose of explanation and are in no way to be construed as limiting of the invention. While the invention has been described with reference to certain embodiments, it is understood that the words that have been used herein are words of description and illustration, rather than words of limitation. For example, although the invention was described in the context of a triaxial electrical contact, it will be appreciated that the techniques and structure described may be equally applied to any type of electrical contact or electrical connector. Also, although the invention has been described with reference to certain components on the electrical contact or connector, it should be appreciated that the configuration described is just one example of a configuration that is capable of providing such an inventive electrical contact or connector. Accordingly, the invention contemplates any other electrical connector or contact, not described in the specification, that satisfies the example provided.

Further, although the invention has been described herein with reference to particular means, materials and embodiments, the invention is not intended to be limited to the particulars disclosed herein. Rather, the invention extends to all functionally equivalent structures, methods and uses, such as are within the scope of the appended claims. Those skilled in the art, having the benefit of the teachings of this specification, may effect numerous modifications thereto and changes may be made without departing from the scope and spirit of the invention in its aspects. Those skilled in the art will appreciate that various changes and adaptations of the invention may be made in the form and details of these embodiments without departing from the true spirit and scope of the invention as defined by the following claims.

What is claimed is:

1. An electrical contact, comprising:
a rear end having a first interface; and
a front end having a second interface to a connector, wherein the second interface prevents a flexible contact medium on the electrical contact from being distorted by the connector.

2. The electrical contact of claim 1, wherein the first interface connects to a connection medium.

3. The electrical contact of claim 1, wherein a front end of the flexible contact medium is isolated from the connector by a flange on the second interface.

4. The electrical contact of claim 3, wherein the flange is a part of a first insulator.

5. The electrical contact of claim 1, wherein a front end of the flexible contact medium is tapered toward an outer boundary of the second interface.

6. The electrical contact of claim 1, wherein a front end of the flexible contact medium is isolated from the connector by a curved rim on the second interface.

7. The electrical contact of claim 1, wherein the second interface permits connection of the connector with a rear portion of the flexible contact medium.

8. The electrical contact of claim 1, wherein the second interface guides the connector.

9. The electrical contact of claim 1, wherein the connector is a triaxial connector.

10. The electrical contact of claim 1, wherein the electrical contact is a male triaxial pin contact.

11. The electrical contact of claim 1, wherein the rear end is tubular.

12. The electrical contact of claim 1, wherein the front end is tubular.

13. The electrical contact of claim 1, wherein the first interface has one or more connection pins.

14. The electrical contact of claim 13, wherein the connection pins include at least one of the following: a center pin, an intermediate pin, and an outer pin.

15. An electrical contact, comprising:
an intermediate contact having a flexible connection medium;
an outer contact surrounding the intermediate contact;
a first insulator surrounding the intermediate contact and the flexible connection medium, wherein the first insulator provides electrical isolation of the intermediate contact from the outer contact, and wherein the first insulator has a front face that protects the flexible connection medium from being distorted by an electrical connector, and wherein the outer contact surrounds the first insulator; and
a center contact surrounded by the intermediate contact.

16. The electrical contact of claim 15, further comprising a second insulator located between the intermediate contact and the center contact, wherein the second insulator provides electrical isolation of the center contact from the intermediate contact.

17. The electrical contact of claim 15, further comprising a flange on the front face, wherein the flange isolates a front portion of the flexible connection medium from the mating connector.

18. The electrical contact of claim 15, further comprising a ledge on the front face, wherein a front portion of the flexible connection medium is located below the ledge.

19. The electrical contact of claim 15, wherein a front portion of the flexible connection medium has a taper, and wherein the taper guides the mating connector within the flexible connection medium.

20. The electrical contact of claim 15, wherein a front portion of the flexible contact medium is tapered toward an outer boundary of the second interface.

21. The electrical contact of claim 15, wherein a front portion of the flexible contact medium is isolated from the connector by a curved rim on the second interface.

22. The electrical contact of claim 15, wherein the second interface permits connection of the connector with a rear portion of the flexible contact medium.

23. The electrical contact of claim 15, further comprising a third insulator surrounding the center contact, wherein the third insulator provides electrical isolation of the center contact.

24. The electrical contact of claim 15, wherein the center contact is connected to a center pin that extends from a rear side of the outer contact such that the center contact is within a plane of the outer contact.

25. The electrical contact of claim 24, wherein the center pin carries a signal.

26. The electrical contact of claim 15, wherein the intermediate contact is connected to an intermediate pin that extends from a rear side of the outer contact such that the center contact is within a plane of the outer contact.

27. The electrical contact of claim 26, wherein the intermediate pin carries a ground potential.

28. The electrical contact of claim 26, wherein the intermediate pin carries a signal.

29. The electrical contact of claim 15, wherein the outer contact is connected to outer pin that extends from a rear side of the outer contact such that the center contact is within a boundary of the outer contact.

30. The electrical contact of claim 29, wherein the outer pin carries a ground potential.

31. An electrical connector, comprising:
a shell;
an electrical contact located within the housing, comprising:
a rear end having a first interface, and
a front end having a second interface to a connector, wherein the second interface prevents the electrical contact from being distorted by the connector; and
at least one other electrical contact located within the shell.

32. The electrical connector of claim 31, wherein the shell is substantially circular and surrounds the electrical contacts.

33. An insulator device for a flexible contact medium, comprising:
a front end having a front opening; and
a rear end having a rear opening, wherein the rear opening is larger than the front opening, and wherein the front opening protects the flexible contact medium from being distorted by a mating connector entering the front opening.

34. The insulator device of claim 33, wherein the front opening has a tapered end smaller than the flexible contact medium.

35. The insulator device of claim 33, wherein the front opening receives a connector.

36. The insulator device of claim 33, wherein the rear opening receives the flexible contact medium.

37. The insulator device of claim 33, wherein the insulator device is a part of a male triaxial electrical connector.

38. The insulator device of claim 33, wherein the insulator device is surrounded by an outer contact.

39. The insulator device of claim 33, wherein the flexible contact medium is an intermediate contact that surrounds a center contact.

40. A pin contact, comprising:
an outer contact;
an intermediate contact surrounded by the outer contact, wherein the intermediate contact has an outer insulative body and an inner flexible conductive body, and wherein the outer insulative body prevents the inner flexible conductive body from being distorted by a connector mating with the pin contact; and
a center contact surrounded by the outer contact and the intermediate contact.

41. The pin contact in claim 40, further comprising a second insulator located between the intermediate contact and the center contact, wherein the second insulator provides electrical isolation of the center contact from the intermediate contact.

42. The pin contact in claim 40, further comprising a third insulator surrounding the center contact, wherein the third insulator provides electrical isolation of the center contact.

43. The pin contact in claim 40, wherein the center contact is connected to a center pin that extends from a rear side of the outer contact such that the center contact is within a plane of the outer contact.
